(19) United States
(12) Patent Application Publication
(10) Pub. No.: US 2020/0303428 A1
(43) Pub. Date: Sep. 24, 2020

(54) MANUFACTURING METHOD OF FLEXIBLE THIN FILM TRANSISTOR BACKPLATE AND FLEXIBLE THIN FILM TRANSISTOR BACKPLATE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Fangmei LIU, Shenzhen, Guangdong (CN); Yuanjun HSU, Shenzhen, Guangdong (CN)

(21) Appl. No.: 16/088,733

(22) PCT Filed: Sep. 6, 2018
(86) PCT No.: PCT/CN2018/104450

§ 371 Date: Sep. 26, 2018

(30) Foreign Application Priority Data
Mar. 29, 2018 (CN) 201810272448.7

(51) Int. Cl. H01L 27/12; H01L 29/786; H01L 29/66

(52) U.S. Cl. CPC H01L 27/1262; H01L 27/1218; H01L 29/66969; H01L 29/7869; H01L 29/78633; H01L 27/1225

(57) ABSTRACT

Provided is a manufacturing method of a flexible thin film transistor backplate. In the manufacturing method; the top gate type metal oxide thin film transistors (T) are formed on the flexible substrate (2). In comparison with the existing bottom gate type low-temperature polysilicon thin film transistors, the consistency of the top gate type metal oxide thin film transistors is good, the electron mobility is high, and the parasitic capacitance is smaller; meanwhile, the lowermost layer of the buffer layer (3) in contact with the flexible substrate (2) is the silicon nitride film (31) according to the manufacturing method of the flexible thin film transistor backplate, the adhesion between the buffer layer (3) and the flexible substrate (2) is good and the top of the buffer layer (3) is the alumina film (33), thus the buffer layer (3) can be made with better water vapor resistance.

### FIELD OF THE INVENTION

The present invention relates to a display technology field, and more particularly to a manufacturing method of a flexible thin film transistor backplate and the flexible thin film transistor backplate.

### BACKGROUND OF THE INVENTION

In the display skill field, Liquid Crystal Display (LCD), Organic Light Emitting Diode (OLED) and other panel display skills have been gradually replaced the CRT displays. The OLED display possesses many outstanding properties of self-illumination, low driving voltage, high luminescence efficiency, fast response, high clarity and contrast, near 180° view angle, wide range of working temperature, applicability of flexible display and large scale full color display. The OLED is considered as the most potential flat panel display technology.

The existing flexible OLED display generally comprises a flexible TFT (Thin Film Transistor Array Substrate) backplate and OLED elements provided on the flexible TFT backplate. The flexible TFT backplate is used for driving the OLED element; the OLED element comprises a substrate, an anode located on the substrate, a hole injection layer located on the anode, a hole transporting layer located on the hole injection layer, an emitting layer located on the hole transporting layer, an electron transporting layer located on the emitting layer, an electron injection layer located on the electron transporting layer and a cathode located on the electron injection layer. The light emitting principle of OLED elements is: as being driven by a certain voltage, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radiative relaxation.

In the prior art, a process of preparing a flexible TFT backplate generally includes preparing a buffer layer on a flexible substrate, and then preparing a bottom gate type thin film transistor with a low temperature poly-silicon (LTPS) semiconductor layer on the buffer layer. However, the uniformity of the large scale LTPS preparation is poor, which limits the application in large scale flexible OLED display devices; meanwhile, the preparation of the buffer layer on the flexible substrate has always been a technical challenge. It is required that the adhesion between the buffer layer and the flexible substrate is good, and the buffer layer needs to have better water vapor resistance. The buffer layer prepared by the existing manufacturing method of the flexible TFT backplate cannot meet these two requirements.

### SUMMARY OF THE INVENTION

An objective of the present invention is to provide a manufacturing method of a flexible thin film transistor backplate, in which the consistency of the thin film transistors is good, the electron mobility is high, and the parasitic capacitance is small, and meanwhile, the adhesion between the buffer layer on the flexible substrate and the flexible substrate can be good, and the buffer layer can be made with better water vapor resistance.

Another objective of the present invention is to provide a flexible thin film transistor backplate, in which the consistency of the thin film transistors is good, the electron mobility is high, and the parasitic capacitance is small for being applied for a large scale flexible OLED display, and meanwhile, the adhesion between the buffer layer on the flexible substrate and the flexible substrate can be good, and the buffer layer can be made with better water vapor resistance.

For realizing the aforesaid objectives, the present invention first provides a manufacturing method of a flexible thin film transistor backplate, comprising:

Step S1, providing a glass substrate, and cleaning and pre baking of the glass substrate;

Step S2; coating a flexible substrate on the glass substrate;

Step S3, first, depositing a silicon nitride film and a silicon oxide film stacked on the silicon nitride film repeatedly on the flexible substrate for several times, and then; depositing an alumina film to form a buffer layer;

Step S4, depositing a light shielding film on the buffer layer and patterning the light shielding film to form a light shielding layer;

Step S5, depositing an insulating layer on the buffer layer and the light shielding layer;

Step S6, depositing a metal oxide film on the insulating layer and patterning the metal oxide film to form a metal oxide active layer over the light shielding layer; which is shielded by the light shielding layer;

Step S7; depositing an insulating film on the metal oxide active layer and the insulating layer;

Step S8, first depositing a first metal film on the insulating film and patterning the first metal film to form a gate above a middle of the metal oxide active layer; and then; etching the insulating film with the gate as a self aligned pattern to leave only a portion of the insulating film covered by the gate to form a gate insulating layer;

Step S9, implementing ion doping to the metal oxide active layer with the gate and the gate insulating layer as a mask so that portions of both ends of the metal oxide active layer, which are not covered by the gate and the gate insulating layer, become conductor portions; and a portion of the metal oxide active layer; which is covered by the gate and the gate insulating layer; becomes a conductive channel;

Step S10, depositing an interlayer insulating layer on the insulating layer, the metal oxide active layer, the gate insulating layer and the gate, and patterning the interlayer insulating layer to form a first via and a second via through the interlayer insulating layer, wherein the first via and the second via respectively expose the conductor portions at the both ends of the metal oxide active layer;

Step S11, depositing a second metal film on the interlayer insulating layer and patterning the second metal film to form a source and a drain, wherein the source and the drain respectively contact the conductor portions at the both ends of the metal oxide active layer through the first via and the second via;

wherein the metal oxide active layer, the gate; the source and the drain constitute a top gate type metal oxide thin film transistor.

The manufacturing method of the flexible thin film transistor backplate further comprises:

Step S12, depositing a passivation layer on the interlayer insulating layer, the source and the drain, and patterning the passivation layer to form a third via through the passivation layer, wherein the third via exposes the drain;

Step S13, removing the glass substrate.

The flexible substrate is a yellow polyimide film or a transparent polyimide film.

In Step S3, depositing the silicon nitride film and the silicon oxide film stacked on the silicon nitride film is repeated twice to three times, and a stacked thickness of the silicon nitride film and the silicon oxide film is 5000 Å to 20000 Å.

In Step S3, an atomic layer deposition process is used to deposit the alumina film; and a thickness of the alumina film is 200 Å to 1000 Å.

In Step S4, a material of the light shielding film is molybdenum.

A material of the insulating layer is silicon oxide, and a thickness of the insulating layer is 1000 Å to 5000 Å; a material of the gate insulating layer is silicon oxide, and a thickness of the gate insulating layer is 1000 Å to 3000 Å; a material of the interlayer insulating layer is silicon oxide or silicon nitride, and a thickness of the interlayer insulating layer is 2000 Å to 10000 Å; a material of the passivation layer is silicon oxide or silicon nitride, and a thickness of the passivation layer is 1000 Å to 5000 Å;

a material of the first metal film and the second metal film is a stack combination of one or more of molybdenum, aluminum, copper and titanium, and a thickness of the first metal film or the second metal film is 2000 Å to 8000 Å.

A material of the metal oxide film is indium gallium zinc oxide, and a thickness of the metal oxide film is 400 Å to 1000 Å;

in Step S9, N-type ion heavy doping is implemented to the metal oxide active layer.

The present invention further provides a flexible thin film transistor backplate, comprising:

a flexible substrate;

a buffer layer covering the flexible substrate; wherein the buffer layer comprises a plurality of silicon nitride films and silicon oxide films, which are alternately stacked from bottom to top, and an alumina film located on top;

a light shielding layer arranged on the buffer layer;

an insulating layer covering the buffer layer and the light shielding layer;

a metal oxide active layer over the light shielding layer, which is arranged on the insulating layer and is shielded by the light shielding layer; wherein the metal oxide active layer comprises a portion of conductive channel in a middle of the metal oxide active layer and conductor portions at both ends of the metal oxide active layer;

a gate insulating layer arranged above the middle of the metal oxide active layer;

a gate arranged on the gate insulating layer;

an interlayer insulating layer covering the insulating layer, the metal oxide active layer; the gate insulating layer and the gate; wherein the interlayer insulating layer comprises a first via and a second via, and the first via and the second via respectively expose the conductor portions at the both ends of the metal oxide active layer; and

a source and a drain arranged on the interlayer insulating layer; wherein the source and the drain respectively contact the conductor portions at the both ends of the metal oxide active layer through the first via and the second via;

wherein the metal oxide active layer, the gate, the source and the drain constitute a top gate type metal oxide thin film transistor.

The flexible thin film transistor backplate further comprises a passivation layer covering the interlayer insulating layer, the source and the drain; wherein the passivation layer comprises a third via, and the third via exposes the drain.

The present invention further provides a manufacturing method of a flexible thin film transistor backplate, comprising:

Step S1, providing a glass substrate, and cleaning and pre baking of the glass substrate;

Step S2, coating a flexible substrate on the glass substrate;

Step S3, first, depositing a silicon nitride film and a silicon oxide film stacked on the silicon nitride film repeatedly on the flexible substrate for several times, and then, depositing an alumina film to form a buffer layer;

Step S4, depositing a light shielding film on the buffer layer and patterning the light shielding film to form a light shielding layer;

Step S5, depositing an insulating layer on the buffer layer and the light shielding layer;

Step S6, depositing a metal oxide film on the insulating layer and patterning the metal oxide film to form a metal oxide active layer over the light shielding layer, which is shielded by the light shielding layer;

Step S7, depositing an insulating film on the metal oxide active layer and the insulating layer;

Step S8, first depositing a first metal film on the insulating film and patterning the first metal film to form a gate above a middle of the metal oxide active layer, and then, etching the insulating film with the gate as a self aligned pattern to leave only a portion of the insulating film covered by the gate to form a gate insulating layer;

Step S9, implementing ion doping to the metal oxide active layer with the gate and the gate insulating layer as a mask so that portions of both ends of the metal oxide active layer, which are not covered by the gate and the gate insulating layer, become conductor portions, and a portion of the metal oxide active layer, which is covered by the gate and the gate insulating layer, becomes a conductive channel;

Step S10, depositing an interlayer insulating layer on the insulating layer, the metal oxide active layer, the gate insulating layer and the gate, and patterning the interlayer insulating layer to form a first via and a second via through the interlayer insulating layer, wherein the first via and the second via respectively expose the conductor portions at the both ends of the metal oxide active layer;

Step S11, depositing a second metal film on the interlayer insulating layer and patterning the second metal film to form a source and a drain, wherein the source and the drain respectively contact the conductor portions at the both ends of the metal oxide active layer through the first via and the second via;

Step S12, depositing a passivation layer on the interlayer insulating layer, the source and the drain, and patterning the passivation layer to form a third via through the passivation layer; wherein the third via exposes the drain;

Step S13, removing the glass substrate;

wherein the metal oxide active layer, the gate, the source and the drain constitute a top gate type metal oxide thin film transistor;

wherein the flexible substrate is a yellow polyimide film or a transparent polyimide film;

wherein in Step S3, depositing the silicon nitride film and the silicon oxide film stacked on the silicon nitride film is repeated twice to three times, and a stacked thickness of the silicon nitride film and the silicon oxide film is 5000 Å to 20000 Å;

wherein in Step S3, an atomic layer deposition process is used to deposit the alumina film, and a thickness of the alumina film is 200 Å to 1000 Å.

The benefits of the present invention are; in the manufacturing method of the flexible thin film transistor backplate provided by the present invention, the top gate type metal oxide thin film transistors are formed on the flexible substrate. In comparison with the existing bottom gate type low-temperature polysilicon thin film transistors; the consistency of the top gate type metal oxide thin film transistors is good, the electron mobility is high, and the parasitic capacitance is smaller; meanwhile, the lowermost layer of the buffer layer in contact with the flexible substrate is the silicon nitride film in the manufacturing method of the flexible thin film transistor backplate provided by the present invention, the adhesion between the buffer layer and the flexible substrate is good and the top of the buffer layer is the alumina film, thus the buffer layer can be made with better water vapor resistance. In the flexible thin film transistor backplate provided by the present invention, the top gate type metal oxide thin film transistors are formed on the flexible substrate, and thus the consistency of the thin film transistors is good, the electron mobility is high, and the parasitic capacitance is smaller for being applied for a large scale flexible OLED display; meanwhile, the lowermost layer of the buffer layer in contact with the flexible substrate is the silicon nitride film, and then, the adhesion between the buffer layer and the flexible substrate is good and the top of the buffer layer is the alumina film, thus the buffer layer can be made with better water vapor resistance.

### BRIEF DESCRIPTION OF THE DRAWINGS

In order to better understand the characteristics and technical aspect of the invention, please refer to the following detailed description and accompanying drawings of the present invention. However, the drawings are provided for reference only and are not intended to be limiting of the invention.

In drawings,

FIG. 1 is a flowchart of a manufacturing method of a flexible thin film transistor backplate according to the present invention;

FIG. 2 is a diagram of Step S1 of a manufacturing method of a flexible thin film transistor backplate according to the present invention;

FIG. 3 is a diagram of Step S2 of a manufacturing method of a flexible thin film transistor backplate according to the present invention;

FIG. 4 is a diagram of Step S3 of a manufacturing method of a flexible thin film transistor backplate according to the present invention;

FIG. 5 is a diagram of Step S4 of a manufacturing method of a flexible thin film transistor backplate according to the present invention;

FIG. 6 is a diagram of Step S5 of a manufacturing method of a flexible thin film transistor backplate according to the present invention;

FIG. 7 is a diagram of Step S6 of a manufacturing method of a flexible thin film transistor backplate according to the present invention;

FIG. 8 is a diagram of Step S7 of a manufacturing method of a flexible thin film transistor backplate according to the present invention;

FIG. 9 and FIG. 10 are diagrams of Step S8 of a manufacturing method of a flexible thin film transistor backplate according to the present invention;

FIG. 11 is a diagram of Step S9 of a manufacturing method of a flexible thin film transistor backplate according to the present invention;

FIG. 12 is a diagram of Step S10 of a manufacturing method of a flexible thin film transistor backplate according to the present invention;

FIG. 13 is a diagram of Step S11 of a manufacturing method of a flexible thin film transistor backplate according to the present invention:

FIG. 14 is a diagram of Step S12 of a manufacturing method of a flexible thin film transistor backplate according to the present invention;

FIG. 15 is a diagram of Step S13 of a manufacturing method of a flexible thin film transistor backplate according to the present invention and also is a structure diagram of a flexible thin film transistor backplate according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

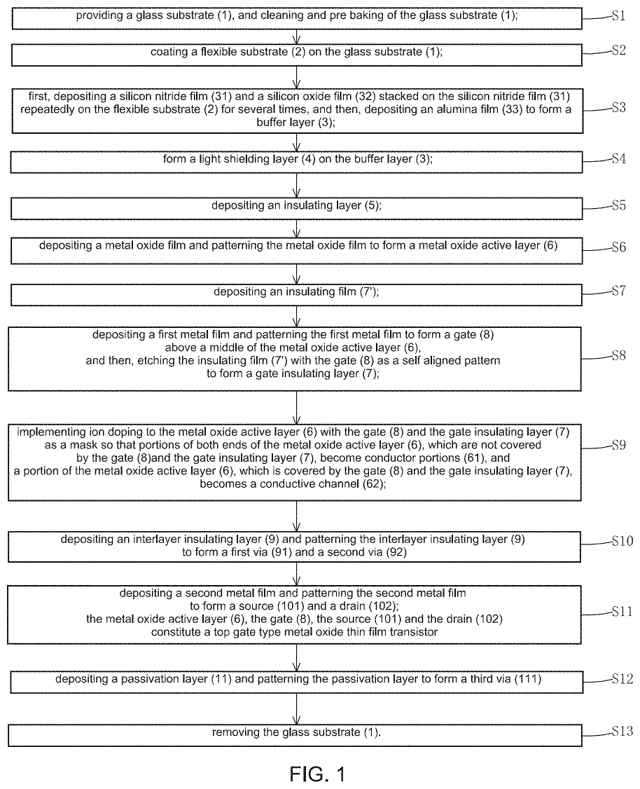

Please refer to FIG. 1. The present invention first provides a manufacturing method of a flexible thin film transistor backplate, comprising:

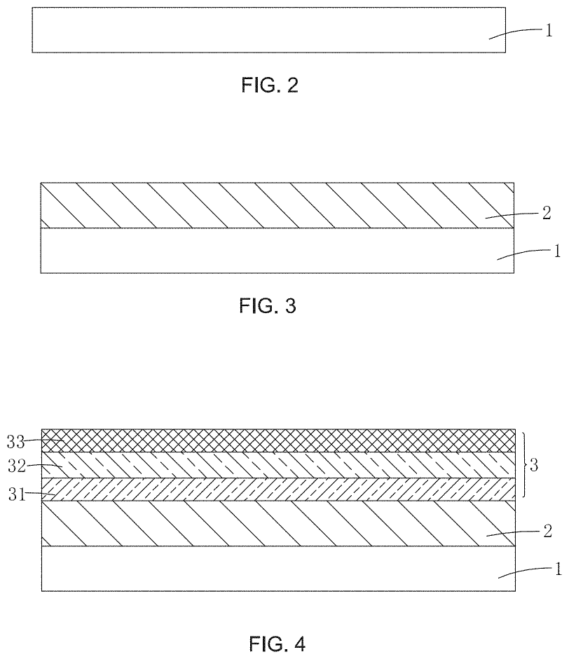

Step 1; as shown in FIG. 2, providing a glass substrate 1, and cleaning and pre baking of the glass substrate 1.

Step S2, as shown in FIG. 3, coating a flexible substrate 2 on the glass substrate 1.

Specifically, the flexible substrate 2 coated in Step S2 is a yellow polyimide (PI) film or a transparent polyimide (PI) film. The yellow PI film has better heat resistance than that of the transparent PI film.

Step S3, as shown in FIG. 4, first, depositing a silicon nitride (SiNx) film 31 and a silicon oxide (SiOx) film 32 stacked on the silicon nitride film 31 repeatedly on the flexible substrate 2, and then, depositing an alumina (Al₂O₃) film 33 to form a buffer layer 3 by an atomic layer deposition process (ALD).

Specifically, in Step S3, depositing the silicon nitride film 31 and the silicon oxide film 32 stacked on the silicon nitride film 31 is repeated twice to three times to increase the waterproof performance of the buffer layer 3. Ultimately, a stacked thickness of the silicon nitride film 31 and the silicon oxide film 32 is 5000 Å to 20000 Å. Since the lowermost layer of the buffer layer 3 in contact with the flexible substrate 2 is the silicon nitride film 31, and the silicon nitride film 31 has strong adhesion and is not easily peeled off, good adhesion between the buffer layer 3 and the flexible substrate 2 can be achieved.

A thickness of the alumina film 33 is 200 Å to 1000 Å. Due to the well compactness of the alumina film 33, the ability of covering defects is strong, and the effect of blocking water vapor is significant. Thus, the buffer layer 3 can be provided with better water vapor resistance.

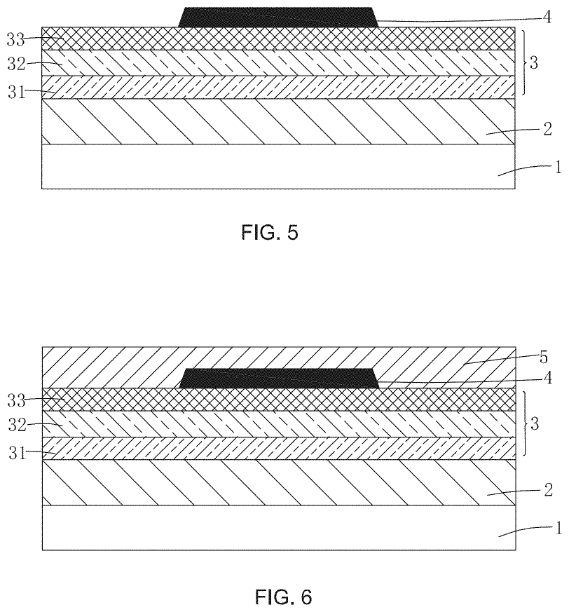

Step S4, as shown in FIG. 5, depositing a light shielding film on the buffer layer 3 and patterning the light shielding film with a mask to form a light shielding layer 4.

Specifically, a material of the light shielding film is opaque metal, such as molybdenum (Mo).

Step S5, as shown in FIG. 6, depositing an insulating layer 5 on the buffer layer 3 and the light shielding layer 4.

Specifically, a material of the insulating layer 5 is silicon oxide, and a thickness of the insulating layer is 1000 Å to 5000 Å.

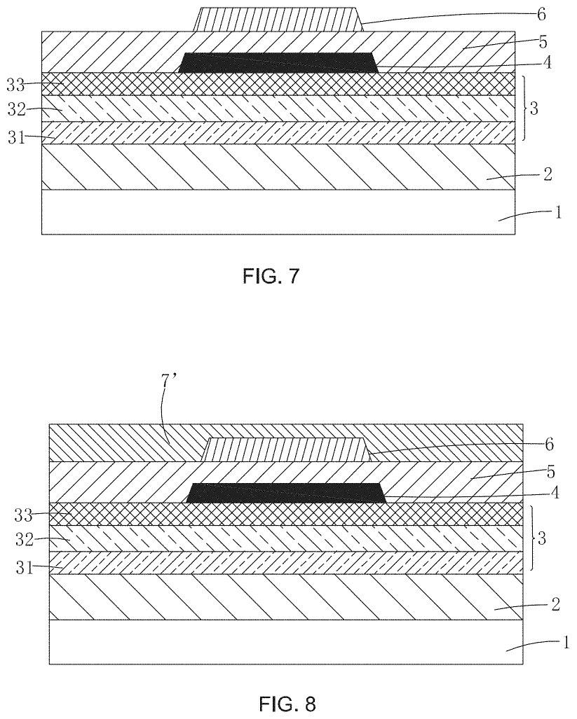

Step S6, as shown in FIG. 7, depositing a metal oxide film on the insulating layer 5 and patterning the metal oxide film with a mask to form a metal oxide active layer 6 over the light shielding layer 4, which is shielded by the light shielding layer 4.

Specifically, a material of the metal oxide film preferably is Indium Gallium Zinc Oxide (IGZO), and a thickness of the metal oxide film is 400 Å to 1000 Å.

Step S7, as shown in FIG. 8, depositing an insulating film 7′ on the metal oxide active layer 6 and the insulating layer 5.

Specifically, a material of the insulating film 7′ is silicon oxide, and a thickness of the gate insulating layer is 1000 Å to 3000 Å.

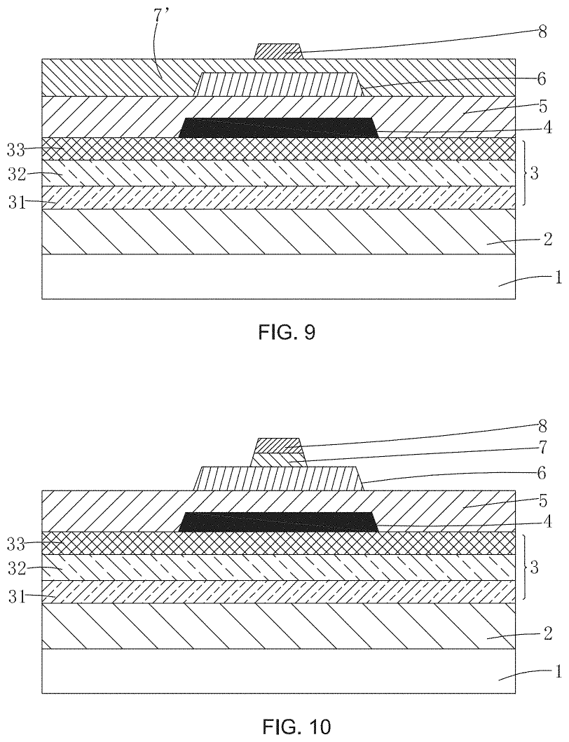

Step S8, as shown in FIG. 9 and FIG. 10, first depositing a first metal film on the insulating film 7′ and patterning the first metal film with a mask to form a gate 8 above a middle of the metal oxide active layer 6, and then, etching the insulating film 7′ with the gate 8 as a self aligned pattern to leave only a portion of the insulating film 7′ covered by the gate 8 to form a gate insulating layer 7.

Specifically, a material of the first metal film can be a stack combination of one or more of molybdenum, aluminum (Al), copper (Cu) and titanium (Ti), and a thickness of the first metal film or the second metal film is 2000 Å to 8000 Å.

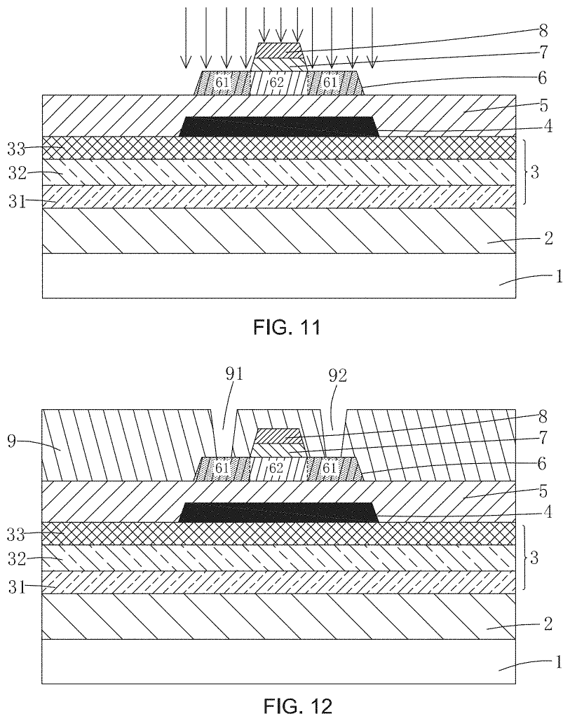

Step S9, as shown in FIG. 11, implementing ion doping to the metal oxide active layer 6 with the gate 8 and the gate insulating layer 7 as a mask so that portions of both ends of the metal oxide active layer 6, which are not covered by the gate 8 and the gate insulating layer 7, become conductor portions 61, and a portion of the metal oxide active layer 6, which is covered by the gate 8 and the gate insulating layer 7, becomes a conductive channel 62.

Specifically, in Step S9, N-type ion (such as phosphorus ion) heavy doping is implemented to the metal oxide active layer 6.

Step S10, as shown in FIG. 12, depositing an interlayer insulating layer 9 on the insulating layer 5, the metal oxide active layer 6, the gate insulating layer 7 and the gate 8, and patterning the interlayer insulating layer 9 to form a first via 91 and a second via 92 through the interlayer insulating layer 9, wherein the first via 91 and the second via 92 respectively expose the conductor portions 61 at the both ends of the metal oxide active layer 6.

Specifically, a material of the interlayer insulating layer 9 is silicon oxide or silicon nitride, and a thickness of the interlayer insulating layer is 2000 Å to 10000 Å.

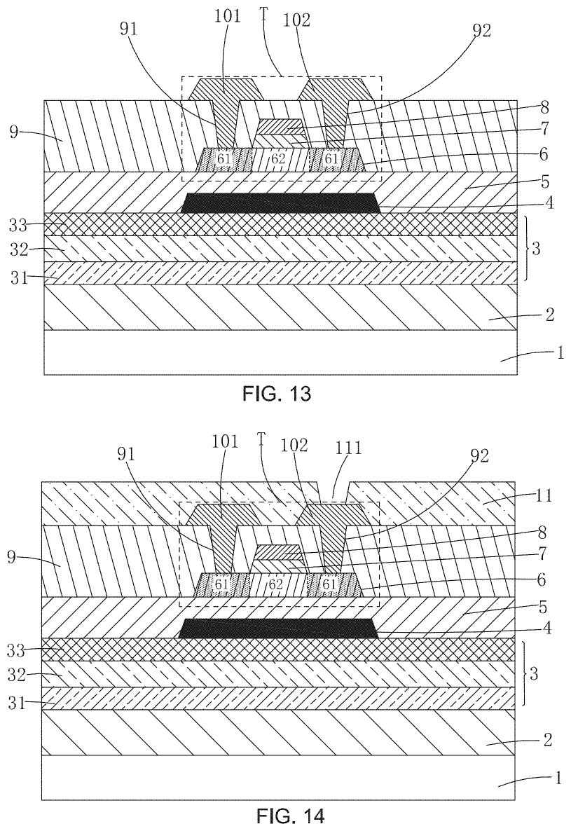

Step S11, as shown in FIG. 13, depositing a second metal film on the interlayer insulating layer 9 and patterning the second metal film with a mask to form a source 101 and a drain 102, wherein the source 101 and the drain 102 respectively contact the conductor portions 61 at the both ends of the metal oxide active layer 6 through the first via 91 and the second via 92.

Specifically, a material of the second metal film can be a stack combination of one or more of molybdenum, aluminum, copper and titanium, and a thickness of the first metal film or the second metal film is 2000 Å to 8000 Å.

After Step S11 is accomplished, the metal oxide active layer 6, the gate 8, the source 101, and the drain 102 constitute a top gate type metal oxide thin film transistor T.

Step S12, as shown in FIG. 14, depositing a passivation layer 11 on the interlayer insulating layer 9, the source 101 and the drain 102, and patterning the passivation layer 11 with a mask to form a third via 111 through the passivation layer 11, wherein the third via 111 exposes the drain 102.

Specifically, a material of the passivation layer 11 is silicon oxide or silicon nitride, and a thickness of the passivation layer is 1000 Å to 5000 Å. The third via hole 111 is used to provide a path for connecting the drain electrode 102 to an OLED element to be manufactured later.

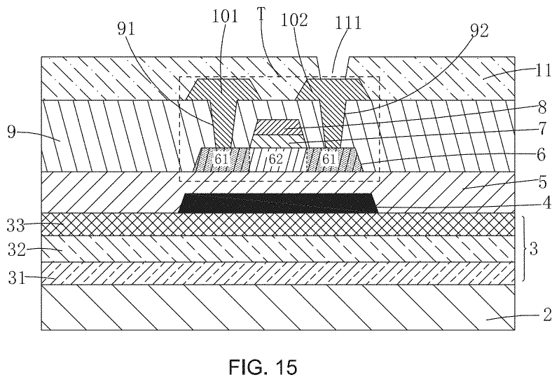

Step S13, as shown in FIG. 15, removing the glass substrate 1.

Then, the manufacture of the flexible thin film transistor backplate is accomplished.

In the manufacturing method of the flexible thin film transistor backplate of the present invention, the top gate type metal oxide thin film transistors T are formed on the flexible substrate 2. In comparison with the bottom gate type metal oxide thin film transistors, the consistency of the top gate type metal oxide thin film transistors T is good; the electron mobility is high, and the parasitic capacitance is smaller. Thus, the flexible thin film transistor backplate prepared by the manufacturing method of the flexible thin film transistor backplate can be applied for a large scale flexible OLED display; meanwhile, the lowermost layer of the buffer layer 3 in contact with the flexible substrate 2 is the silicon nitride film 31 according to the manufacturing method of the flexible thin film transistor backplate, and then, the adhesion between the buffer layer 3 and the flexible substrate 2 is good and the top of the buffer layer 3 is the alumina film 33, thus the buffer layer 3 can be made with better water vapor resistance.

Please refer to FIG. 15. The present invention further provides a flexible thin film transistor backplate manufactured by the aforesaid manufacturing method of a flexible thin film transistor backplate, comprises:

a flexible substrate 2;

a buffer layer 3 covering the flexible substrate 2; wherein the buffer layer 3 comprises a plurality of silicon nitride films 31 and silicon oxide films 32, which are alternately stacked from bottom to top, and an alumina film 33 located on top;

a light shielding layer 4 arranged on the buffer layer 3;

an insulating layer 5 covering the buffer layer 3 and the light shielding layer 4;

a metal oxide active layer 6 over the light shielding layer 4, which is arranged on the insulating layer 5 and is shielded by the light shielding layer 4; wherein the metal oxide active layer 6 comprises a portion of conductive channel 62 in a middle of the metal oxide active layer and conductor portions 61 at both ends of the metal oxide active layer;

a gate insulating layer 7 arranged above the middle of the metal oxide active layer 6;

a gate 8 arranged on the gate insulating layer 7;

an interlayer insulating layer 9 covering the insulating layer 5, the metal oxide active layer 6, the gate insulating layer 7 and the gate 8; wherein the interlayer insulating layer 9 comprises a first via 91 and a second via 92, and the first via 91 and the second via 92 respectively expose the conductor portions 61 at the both ends of the metal oxide active layer 6;

a source 101 and a drain 102 arranged on the interlayer insulating layer 9; wherein the source 101 and the drain 102 respectively contact the conductor portions 61 at the both ends of the metal oxide active layer 6 through the first via 91 and the second via 92; and

a passivation layer 11 covering the interlayer insulating layer 9, the source 101 and the drain 102; wherein the passivation layer 9 comprises a third via 111, and the third via 111 exposes the drain 102;

the metal oxide active layer 6, the gate 8; the source 101, and the drain 102 constitute a top gate type metal oxide thin film transistor T.

Specifically: the flexible substrate 2 is a yellow PI film or a transparent PI film;

in the buffer layer 3, a stacked thickness of the silicon nitride film 31 and the silicon oxide film 32 is 5000 Å to 20000 Å. Since the lowermost layer of the buffer layer 3 in contact with the flexible substrate 2 is the silicon nitride film 31, and the silicon nitride film 31 has strong adhesion and is not easily peeled off, good adhesion between the buffer layer 3 and the flexible substrate 2 can be achieved; a thickness of the alumina film 33 is 200 Å to 1000 Å, and due to the well compactness of the alumina film 33, the ability of covering defects is strong, and the effect of blocking water vapor is significant. Thus, the buffer layer 3 can be provided with better water vapor resistance;

a material of the light shielding layer 4 is opaque metal, such as molybdenum;

a material of the insulating layer 5 is silicon oxide, and a thickness of the insulating layer is 1000 Å to 5000 Å;

a material of the metal oxide layer 6 preferably is IGZO, and a thickness of the metal oxide layer is 400 Å to 1000 Å; the conductor portions 61 of the metal oxide layer 6 is doped with N-type ion (such as phosphorus ion);

a material of the insulating layer 7 is silicon oxide, and a thickness of the gate insulating layer is 1000 Å to 3000 Å;

a material of the gate 8 can be a stack combination of one or more of molybdenum, aluminum, copper and titanium, and a thickness of the gate is 2000 Å to 8000 Å;

a material of the interlayer insulating layer 9 is silicon oxide or silicon nitride; and a thickness of the interlayer insulating layer is 2000 Å to 10000 Å;

a material of the source 101 and the drain 102 can be a stack combination of one or more of molybdenum, aluminum, copper and titanium, and a thickness of the gate is 2000 Å to 8000 Å;

a material of the passivation layer 11 is silicon oxide or silicon nitride, and a thickness of the passivation layer is 1000 Å to 5000 Å.

In conclusion, in the manufacturing method of the flexible thin film transistor backplate of the present invention, the top gate type metal oxide thin film transistors are formed on the flexible substrate. In comparison with the existing bottom gate type low-temperature polysilicon thin film transistors, the consistency of the top gate type metal oxide thin film transistors is good, the electron mobility is high, and the parasitic capacitance is small; meanwhile, the lowermost layer of the buffer layer in contact with the flexible substrate is the silicon nitride film according to the manufacturing method of the flexible thin film transistor backplate of the present invention, the adhesion between the buffer layer and the flexible substrate is good and the top of the buffer layer is the alumina film, thus the buffer layer can be made with better water vapor resistance. In the flexible thin film transistor backplate of the present invention, the top gate type metal oxide thin film transistors are formed on the flexible substrate, and thus the consistency of the thin film transistors is good, the electron mobility is high, and the parasitic capacitance is smaller for being applied for a large scale flexible OLEO display; meanwhile, the lowermost layer of the buffer layer in contact with the flexible substrate is the silicon nitride film, and then, the adhesion between the buffer layer and the flexible substrate is good and the top of the buffer layer is the alumina film, thus the buffer layer can be made with better water vapor resistance.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacturing method of a flexible thin film transistor backplate, comprising:
Step S1, providing a glass substrate, and cleaning and pre baking of the glass substrate;
Step S2, coating a flexible substrate on the glass substrate;
Step S3, first, depositing a silicon nitride film and a silicon oxide film stacked on the silicon nitride film repeatedly on the flexible substrate for several times, and then, depositing an alumina film to form a buffer layer;
Step S4, depositing a light shielding film on the buffer layer and patterning the light shielding film to form a light shielding layer;
Step S5, depositing an insulating layer on the buffer layer and the light shielding layer;
Step S6, depositing a metal oxide film on the insulating layer and patterning the metal oxide film to form a metal oxide active layer over the light shielding layer, which is shielded by the light shielding layer;
Step S7, depositing an insulating film on the metal oxide active layer and the insulating layer;
Step S8, first depositing a first metal film on the insulating film and patterning the first metal film to form a gate above a middle of the metal oxide active layer, and then, etching the insulating film with the gate as a self aligned pattern to leave only a portion of the insulating film covered by the gate to form a gate insulating layer;
Step S9, implementing ion doping to the metal oxide active layer with the gate and the gate insulating layer as a mask so that portions of both ends of the metal oxide active layer, which are not covered by the gate and the gate insulating layer, become conductor portions, and a portion of the metal oxide active layer, which is covered by the gate and the gate insulating layer, becomes a conductive channel;
Step S10, depositing an interlayer insulating layer on the insulating layer, the metal oxide active layer, the gate insulating layer and the gate, and patterning the interlayer insulating layer to form a first via and a second via through the interlayer insulating layer, wherein the first via and the second via respectively expose the conductor portions at the both ends of the metal oxide active layer;
Step S11, depositing a second metal film on the interlayer insulating layer and patterning the second metal film to form a source and a drain, wherein the source and the drain respectively contact the conductor portions at the both ends of the metal oxide active layer through the first via and the second via;
wherein the metal oxide active layer, the gate, the source and the drain constitute a top gate type metal oxide thin film transistor.

2. The manufacturing method of the flexible thin film transistor backplate according to claim 1, further comprising:
Step S12, depositing a passivation layer on the interlayer insulating layer, the source and the drain, and patterning the passivation layer to form a third via through the passivation layer, wherein the third via exposes the drain;
Step S13, removing the glass substrate.

3. The manufacturing method of the flexible thin film transistor backplate according to claim 1, wherein the flexible substrate is a yellow polyimide film or a transparent polyimide film.

4. The manufacturing method of the flexible thin film transistor backplate according to claim 1, wherein in Step S3, depositing the silicon nitride film and the silicon oxide film stacked on the silicon nitride film is repeated twice to three times, and a stacked thickness of the silicon nitride film and the silicon oxide film is 5000 Å to 20000 Å.

5. The manufacturing method of the flexible thin film transistor backplate according to claim 1, wherein in Step S3, an atomic layer deposition process is used to deposit the alumina film, and a thickness of the alumina film is 200 Å to 1000 Å.

6. The manufacturing method of the flexible thin film transistor backplate according to claim 1, wherein in Step S4, a material of the light shielding film is molybdenum.

7. The manufacturing method of the flexible thin film transistor backplate according to claim 2, wherein a material of the insulating layer is silicon oxide, and a thickness of the insulating layer is 1000 Å to 5000 Å; a material of the gate insulating layer is silicon oxide, and a thickness of the gate insulating layer is 1000 Å to 3000 Å; a material of the interlayer insulating layer is silicon oxide or silicon nitride, and a thickness of the interlayer insulating layer is 2000 Å to 10000 Å; a material of the passivation layer is silicon oxide or silicon nitride, and a thickness of the passivation layer is 1000 Å to 5000 Å;
a material of the first metal film and the second metal film is a stack combination of one or more of molybdenum, aluminum, copper and titanium, and a thickness of the first metal film or the second metal film is 2000 Å to 8000 Å.

8. The manufacturing method of the flexible thin film transistor backplate according to claim 1, wherein a material of the metal oxide film is indium gallium zinc oxide, and a thickness of the metal oxide film is 400 Å to 1000 Å;
in Step S9, N-type ion heavy doping is implemented to the metal oxide active layer.

9. A flexible thin film transistor backplate, comprising:
a flexible substrate;
a buffer layer covering the flexible substrate; wherein the buffer layer comprises a plurality of silicon nitride films and silicon oxide films, which are alternately stacked from bottom to top, and an alumina film located on top;
a light shielding layer arranged on the buffer layer;
an insulating layer covering the buffer layer and the light shielding layer;
a metal oxide active layer over the light shielding layer, which is arranged on the insulating layer and is shielded by the light shielding layer; wherein the metal oxide active layer comprises a portion of conductive channel in a middle of the metal oxide active layer and conductor portions at both ends of the metal oxide active layer;
a gate insulating layer arranged above the middle of the metal oxide active layer;
a gate arranged on the gate insulating layer;
an interlayer insulating layer covering the insulating layer, the metal oxide active layer, the gate insulating layer and the gate; wherein the interlayer insulating layer comprises a first via and a second via, and the first via and the second via respectively expose the conductor portions at the both ends of the metal oxide active layer; and
a source and a drain arranged on the interlayer insulating layer; wherein the source and the drain respectively contact the conductor portions at the both ends of the metal oxide active layer through the first via and the second via;
wherein the metal oxide active layer, the gate, the source and the drain constitute a top gate type metal oxide thin film transistor.

10. The flexible thin film transistor backplate according to claim 9, further comprising a passivation layer covering the interlayer insulating layer, the source and the drain; wherein the passivation layer comprises a third via, and the third via exposes the drain.

11. A manufacturing method of a flexible thin film transistor backplate, comprising:
Step S1, providing a glass substrate, and cleaning and pre baking of the glass substrate;
Step S2, coating a flexible substrate on the glass substrate;
Step S3, first, depositing a silicon nitride film and a silicon oxide film stacked on the silicon nitride film repeatedly on the flexible substrate for several times, and then, depositing an alumina film to form a buffer layer;
Step S4, depositing a light shielding film on the buffer layer and patterning the light shielding film to form a light shielding layer;
Step S5, depositing an insulating layer on the buffer layer and the light shielding layer;
Step S6, depositing a metal oxide film on the insulating layer and patterning the metal oxide film to form a metal oxide active layer over the light shielding layer, which is shielded by the light shielding layer;
Step S7, depositing an insulating film on the metal oxide active layer and the insulating layer;
Step S8, first depositing a first metal film on the insulating film and patterning the first metal film to form a gate above a middle of the metal oxide active layer, and then, etching the insulating film with the gate as a self aligned pattern to leave only a portion of the insulating film covered by the gate to form a gate insulating layer;
Step S9, implementing ion doping to the metal oxide active layer with the gate and the gate insulating layer as a mask so that portions of both ends of the metal oxide active layer, which are not covered by the gate and the gate insulating layer, become conductor portions, and a portion of the metal oxide active layer, which is covered by the gate and the gate insulating layer, becomes a conductive channel;
Step S10, depositing an interlayer insulating layer on the insulating layer, the metal oxide active layer, the gate insulating layer and the gate, and patterning the interlayer insulating layer to form a first via and a second via through the interlayer insulating layer, wherein the first via and the second via respectively expose the conductor portions at the both ends of the metal oxide active layer;
Step S11, depositing a second metal film on the interlayer insulating layer and patterning the second metal film to form a source and a drain, wherein the source and the drain respectively contact the conductor portions at the both ends of the metal oxide active layer through the first via and the second via;
Step S12, depositing a passivation layer on the interlayer insulating layer, the source and the drain, and patterning the passivation layer to form a third via through the passivation layer, wherein the third via exposes the drain;
Step S13, removing the glass substrate;
wherein the metal oxide active layer, the gate, the source and the drain constitute a top gate type metal oxide thin film transistor;
wherein the flexible substrate is a yellow polyimide film or a transparent polyimide film;
wherein in Step S3, depositing the silicon nitride film and the silicon oxide film stacked on the silicon nitride film is repeated twice to three times, and a stacked thickness of the silicon nitride film and the silicon oxide film is 5000 Å to 20000 Å;
wherein in Step S3, an atomic layer deposition process is used to deposit the alumina film, and a thickness of the alumina film is 200 Å to 1000 Å.

12. The manufacturing method of the flexible thin film transistor backplate according to claim 11, wherein in Step S4, a material of the light shielding film is molybdenum.

13. The manufacturing method of the flexible thin film transistor backplate according to claim 11, wherein a material of the insulating layer is silicon oxide, and a thickness of the insulating layer is 1000 Å to 5000 Å; a material of the gate insulating layer is silicon oxide, and a thickness of the gate insulating layer is 1000 Å to 3000 Å; a material of the interlayer insulating layer is silicon oxide or silicon nitride, and a thickness of the interlayer insulating layer is 2000 Å to 10000 Å; a material of the passivation layer is silicon oxide or silicon nitride, and a thickness of the passivation layer is 1000 Å to 5000 Å;
a material of the first metal film and the second metal film is a stack combination of one or more of molybdenum, aluminum, copper and titanium, and a thickness of the first metal film or the second metal film is 2000 Å to 8000 Å.

14. The manufacturing method of the flexible thin film transistor backplate according to claim 11, wherein a material of the metal oxide film is indium gallium zinc oxide, and a thickness of the metal oxide film is 400 Å to 1000 Å;
in Step S9, N-type ion heavy doping is implemented to the metal oxide active layer.
